(19) United States
(12) Patent Application Publication
(10) Pub. No.: US 2009/0040738 A1
(43) Pub. Date: Feb. 12, 2009

(54) Card-extender stabilizing kit for use in conjunction with computer-device testing assembly

(75) Inventors: Gary D. Shay, Nichols, NY (US); Laurence C. Sullivan, Newark Valley, NY (US)

Correspondence Address: LOUIS J FRANCO;LAW OFFICE OF LOUIS J FRANCO, 250 ARBOR, LUNENBURG, MA, 01462, US

(73) Assignee: Lockheed Martin Corporation

(21) Appl. No.: 12/221,984

(22) Filed: Aug. 8, 2008

Related U.S. Application Data
(60) Provisional application No. 60/964,109, filed on Aug. 9, 2007.

(51) Int. Cl. H05K 5/00

(52) U.S. Cl. 361/752

(57) ABSTRACT

A card-extender stabilizing kit is configured for use in conjunction with (a) a computer-device testing unit including testing circuitry having electrical connectors and being housed in a testing-unit housing and (b) a card extender having (i) a first set of electrical connectors configured for selective coupling with the testing-circuitry connectors, (ii) a second set of electrical connectors configured for coupling with the electrical connectors of a device under test, and (iii) first and second card-extender edges extending between the first and second sets of electrical connectors. The stabilizing kit comprises first and second stabilizers. Each stabilizer includes a mount configured for coupling with the housing of a computer-device testing unit and a card-extender bracket including a bracket groove configured for slidably receiving one of the card-extender edges. When the stabilizers are coupled to a testing-unit housing, the bracket grooves are spaced apart such that (i) the card-extender can be positioned between the bracket grooves and supported by virtue of supporting engagement between each of the first and second card-extender edges and one of the card-extender brackets; (ii) the first set of electrical connectors can be coupled to the testing-circuitry connectors and (iii) the second set of electrical connectors can be coupled with the electrical connectors of a device under test.

### PROVISIONAL PRIORITY CLAIM

Priority based on Provisional Application Ser. No. 60/964,109, filed Thursday, Aug. 9, 2007, and entitled “CARD-EXTENDER STABILIZING KIT FOR USE IN CONJUNCTION WITH COMPUTER-DEVICE TESTING ASSEMBLY,” is claimed.

### BACKGROUND

It is common practice to perform testing of circuit boards, such as computer system boards (e.g., motherboards and the like) prior to their sale or use in a computer system product. As computer system boards have evolved, an ever-increasing level of functionality has been built into the boards, such as integrated video subsystems, audio systems, network interfaces, modem circuitry, and the like. Testing to verify the integrity of such functionality is often performed during quality control operations, either on an individual board basis, or using a random sampling scheme.

Generally, in order to test a computer system board, the board is mounted or otherwise coupled to testing circuitry incorporated in a test plate or the like, and input connectors (e.g. pins or sockets) are manually mated with corresponding system board connectors to provide input power signals to the system board and to coupled input/output (I/O) ports and the like to electronic test equipment that is used to test the performance of the system board via a variety of test operations. Typically, the testing circuitry is incorporated within a testing unit that includes a housing or cabinet in which the testing circuitry is at least partially enclosed for protection from mechanical damage. Because some circuit-board-testing units are designed such that the testing circuitry is housed relatively deeply within the unit housing, devices known as “card extenders” have been developed. A typical card-extender includes opposed first and second edges including, respectively, first and second connector assemblies. Each of the first and second connector assemblies includes a plurality of connectors (e.g., pin or socket type). Connectors in the first connector assembly are connected to connectors in the second connector assembly through electrical circuitry that extends between the first and second edges of the card extender. The first connector assembly includes connectors that mate with testing-circuitry connectors contained within the testing-unit housing. The second connector assembly includes connectors configured for mating with a corresponding set of connectors included on a circuit board to be tested or “device under test (DUT).” Some card extenders do more than merely provide a communicative link between a device under test and the testing circuitry of a testing unit and, accordingly, may include testing circuitry of their own.

Depending on the configurations of the testing unit, card-extender and the device under test, two problems attendant to the use of card extenders are (i) large card extenders physically supported within a testing unit only by virtue of mating engagement between connectors of the first connector assembly with testing-circuitry connectors are unstable and (ii) the connection between the device under test and the card extender is frequently unstable. Movement between the card extender and the testing circuitry and/or between the card extender and the device under test has caused damage to circuitry, card extenders and devices under test.

Accordingly, there exists a need for a card-extender stabilizing kit for use in assembled conjunction with the housing of a computer-device testing unit, a card-extender, and a device under test in order to stabilize the card-extender relative to the testing unit and, in various situations, the device under test relative to the card extender.

### SUMMARY

An illustrative computer-device testing assembly for testing a computer device includes a computer-device testing unit including testing circuitry at least partially housed in a testing-unit housing and having electrical testing-circuitry connectors for electrical coupling with electrical connectors of the device to be tested (device under test). The illustrative testing assembly further includes a card extender having (i) a first connector assembly including a first set of electrical connectors coupled with the testing-circuitry connectors, (ii) a second connector assembly, opposite the first connector assembly, and including a second set of electrical connectors configured for selective coupling with the electrical connectors of a device under test, and (iii) opposed and parallel first and second card-extender edges extending between the first and second connector assemblies.

The card extender is stabilized, relative to the testing unit housing, by a card-extender stabilizing kit including first and second card-extender stabilizers. Each stabilizer has a mount coupled with the testing-unit housing and an elongated rigid card-extender bracket including a bracket groove. The stabilizers are coupled to the testing-unit housing such that the bracket grooves are spaced apart and aligned in parallel. The card-extender is supported between the bracket grooves by virtue of supporting engagement between at least a portion of each of the first and second card-extender edges and one of the card-extender brackets. Moreover, the bracket grooves extend along the first and second card-extender edges in a manner such that the second set of electrical connectors is unobstructed for selective coupling with the electrical connectors of a computer device to be tested. As discussed in the detailed description relative to a particular illustrative version, the “supporting engagement” between each of the first and second card-extender edges and one of the card-extender brackets is, in alternative versions, “direct” or “indirect.” More specifically, a portion of the card-extender bracket defining a bracket groove may be in direct physical contact with an edge of the card-extender or a third element may be physical interposed between the card-extender edge and the portion of the card-extender bracket defining the bracket groove. Examples of interposed “third elements” include (i) a spacer used to compensate for any difference between the thickness of a card-extender edge and the width of a bracket groove; (ii) a spacer to compensate for a difference in width of the card-extender (i.e., between the first and second card-extender edges) and the distance between the bracket grooves of the first and second stabilizers; and a device lock used to retain a device under test in coupled engagement with the card-extender. It will therefore be appreciated that when a third element is interposed between at least one of the brackets and one of the first and second card-extender edges, that card-extender edge may not actually be “within” the bracket groove of the stabilizer physically supporting that card-extender edge, even while the first and second card-extender edges are “between the bracket grooves.” In other words, the width of a card-extender supported by and between first and second card-extender brackets need not be co-extensive with the distance between the corresponding bracket grooves defined within the first and second card-extender brackets.

In various circumstances, the device under test is a card-type computer device including opposed first and second device edges and a third edge (i) that extends between the first and second edges and (ii) along which is disposed the set of electrical connectors configured for coupling to the testing-circuitry connectors. Various versions of the stabilizer kit facilitate stabilization of the device under test, relative to the card extender, by the extension of the bracket grooves beyond the second connector assembly of the card extender such that the first and second device edges of a device under test, with the electrical connectors thereof coupled to the electrical connectors of the second connector assembly, are at least partially disposed between the bracket grooves of the first and second stabilizers such that at least one of the card-extender brackets stabilizes the device under test relative to the card extender by virtue of supporting engagement between one of the first and second device edges and the at least one card-extender bracket. It will be appreciated that the “supporting engagement” between the device under test and the card-extender brackets may be “direct” or “indirect” in a manner similar to that explained previously in connection with the supporting engagement between the card extender and at least one card-extender bracket.

The mount of each stabilizer may be any of various devices and configurations including, by way of non-limiting example, a clamping structure or a base that is fastened by screws or bolts and nuts, for example, to the testing-unit housing. In one version of the stabilizing kit, the mounts of the first and second stabilizers comprise, respectively, a first elongated post extending longitudinally along a first post axis and a second elongated post extending longitudinally along a second post axis. In a version of the computer-device testing assembly in which the mounts are posts, the testing-unit housing further includes first and second structural portions, wherein the first structural portion has defined therein a first-post channel configured for selective sliding receipt and retention of the first post and the second structural portion has defined therein a second-post channel configured for selective sliding receipt and retention of the first post. In order to prevent rotation of the first and second posts in their respective post channels, one version is configured such that (i) the first post and the first-post channel are of mutually complimentary keyed (e.g. non-circular) cross-sectional configurations and (ii) the second post and the second-post channel are of mutually complimentary keyed cross-sectional configurations.

Representative, non-limiting embodiments are more completely described and depicted in the following detailed description and the accompanying drawings.

### BRIEF DESCRIPTION OF THE DRAWINGS

FIG. 1 shows an illustrative computer-device testing assembly including a computer-device testing unit, a card extender including circuitry electrically coupled with circuitry in the computer-device testing unit, and a card-extender stabilizing kit including first and second stabilizers for supporting the card extender relative to the testing unit;

FIG. 1A. shows an alterative view of the computer-device testing assembly of FIG. 1;

FIG. 2 depicts the card-extender of FIGS. 1 and 1A removed from the computer-device testing unit; and

FIG. 3 portrays, in isolation, the first and second stabilizers of the stabilizing kit shown in FIGS. 1 and 1A.

### DETAILED DESCRIPTION

The following description of various embodiments of a card-extender stabilizer is illustrative in nature and is therefore not intended to limit the scope of the invention or its application of uses.

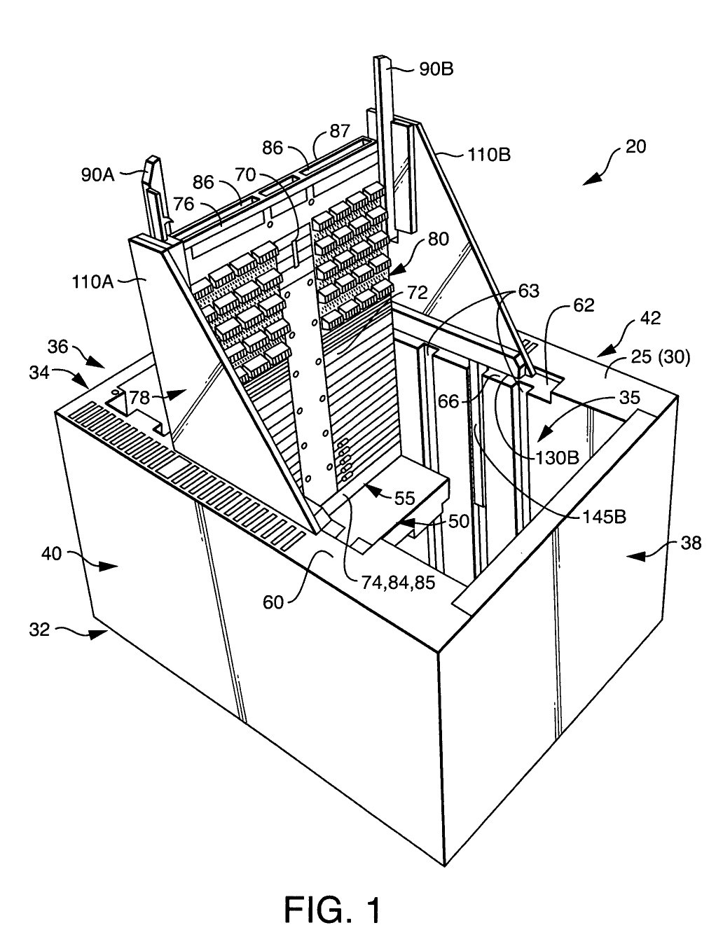

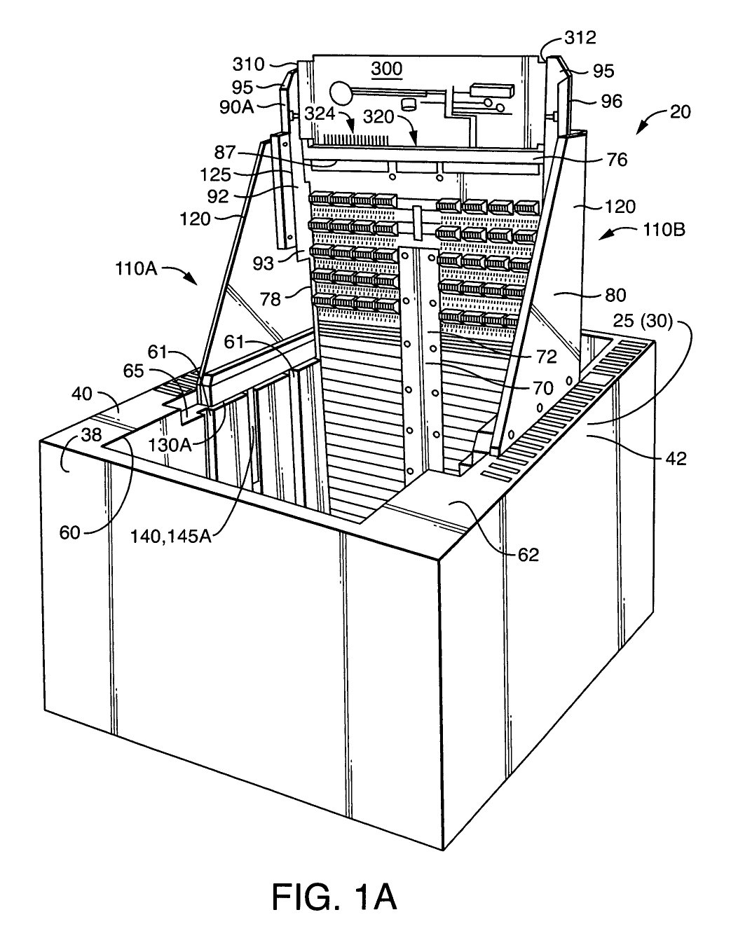

Referring to FIGS. 1 and 1A, an illustrative computer-device testing unit 20 includes a testing-unit housing 25 which, in the case of FIGS. 1 and 1A, is in the form of a cabinet 30. The cabinet-style testing-unit housing 30 has a bottom end 32, a top end 34, opposed back and front walls 36 and 38 and opposed left and right walls 40 and 42 extending between the bottom and top ends 32 and 34. The testing-unit housing 30 encloses (at least partially) electrical testing circuitry 50 having electrical testing-circuitry connectors 55. In the illustrative testing unit 20 of FIGS. 1 and 1A, the testing-circuitry connectors 55 are located more proximate to the bottom end 32 than the top end 34 of the housing 30, and the top end 34 includes a top-end opening 35 through which access to the testing-circuitry connectors 55 is provided.

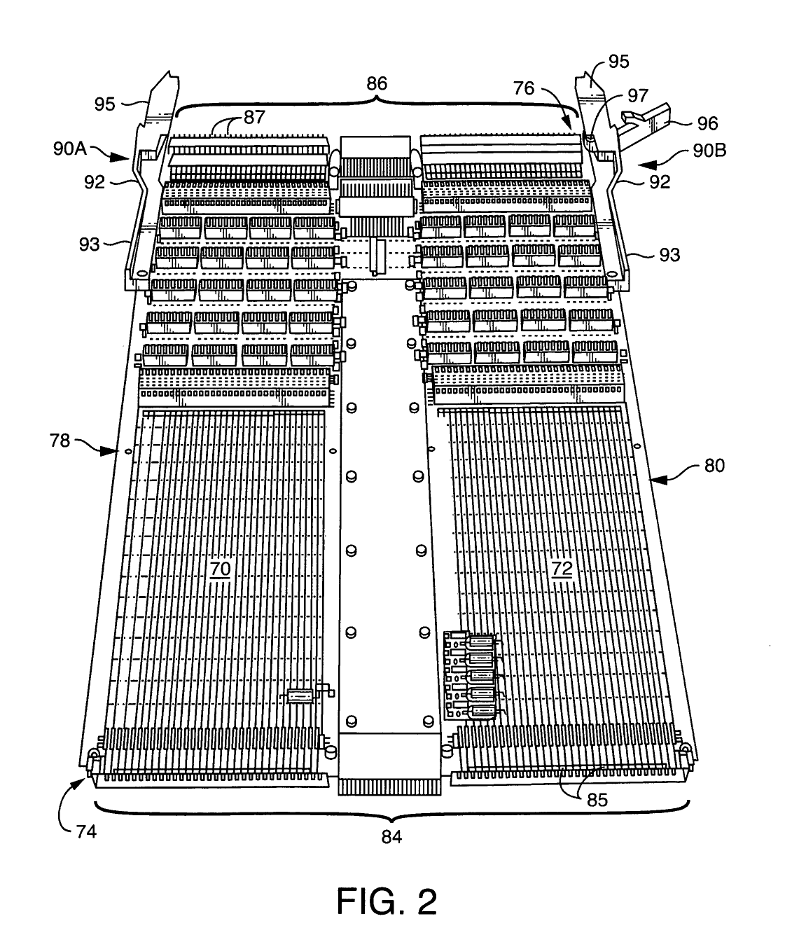

With continued reference to FIGS. 1 and 1A, a card-extender 70 is shown situated within the testing-unit housing 30. The card-extender 70 is of the general type shown in FIG. 2 and includes a generally rectangular, self-supporting board-type substrate or chassis 72 with opposed first and second ends 74 and 76 and opposed and parallel first and second edges 78 and 80 extending between the first and second ends 74 and 76. Situated along, respectively, the first and second ends 74 and 76 are (i) a first connector assembly 84 including a first set of electrical connectors 85 configured for selective coupling with the testing-circuitry connectors 55 of the testing unit 20 and (ii) a second connector assembly 86 including a second set of electrical connectors 87 configured for selective coupling with electrical connectors of a computer device to be tested, as explained further in the description below.

Referring to FIG. 1A, an illustrative device to be tested (hereinafter “device under test” or “DUT” 300) is shown. The device under test 300 is a circuit-board-type device and includes opposed first and second device edges 310 and 312 and a third edge 320 along which are disposed electrical connectors 324. In FIG. 1A, the electrical connectors 324 of the DUT 300 are cooperatively coupled with the electrical connectors 87 of the second connector assembly 86 extending along the second end 76 of the card-extender 70.

Shown in conjunction with the card-extender 70 in FIGS. 1, 1A and 2 are first and second device locks 90A and 90B. Each of device locks 90A and 90B includes an elongated lock member 92 including a first portion 93 attached to a respective one of the first and second edges 78 and 80 of the card-extender 70. In the illustrative case depicted, the device locks 90A and 90B are removably attached to the card-extender 70 via bolts and nuts, but in alternative versions the device locks 90A and 90B are selectively attachable by other mechanisms or permanently attached to the card-extender 70. Each lock member 92 further includes a second portion 95 that extends beyond the second connector assembly 86 and contactably engages and supports a DUT 300 as shown in FIG. 1A. The lock member 92 of each device lock 90A and 90B pivotably supports a lever 96 including a lug 97 that selectively engages a portion of a DUT 300 and at least one of (i) draws into and (ii) retains in mutual coupling engagement the electrical connectors 324 of the DUT 300 and the electrical connectors 87 of the second connector assembly 86.

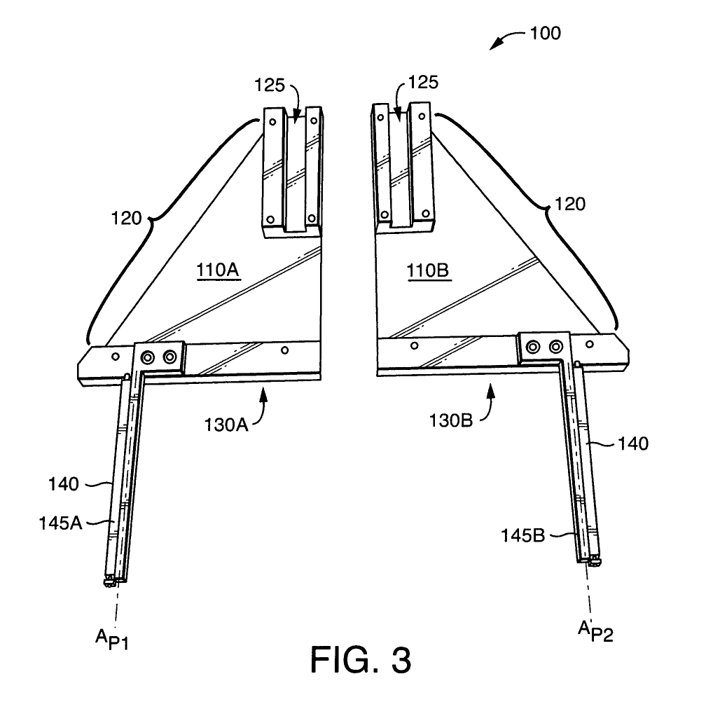

Referring to FIGS. 1, 1A and 3, the card-extender 70 is supported within the testing-unit housing 25 by a card-extender stabilizing kit 100 including first and second stabilizers 110A and 110B. To the extent that a portion or sub-element of one of the stabilizers 110A and 110B is specifically and individually referenced, a respective one of the letters “A” and “B” is annexed to the reference number in the text. Correlatively, to the extent that corresponding components or sub-elements of the stabilizers 110A and 110B are referenced collectively, no reference letter (“A” or “B”) is included in the reference number. Moreover, the first and second stabilizers 110A and 110B may themselves be referred to collectively by the reference number “110.” Each of stabilizers 110A and 110B includes an elongated rigid card-extender bracket 120 including a bracket groove 125. Depending from the card-extender bracket 120 is a mount 140 configured for selective coupling with the testing-unit housing 25. Referring to FIGS. 1 and 1A, when the stabilizers 110A and 110B are operatively coupled to the testing-unit housing 25, the bracket grooves 125 are spaced apart and aligned in parallel such that the card-extender 70 can be positioned between the brackets 120 of stabilizers 110A and 110B and at least a portion of each of the first and second card-extender edges 78 and 80 can be supported by a bracket groove 125 of one of the first and second stabilizers 110A and 110B. Moreover, the brackets 120 of the stabilizers 110 support the card-extender 70 such that (i) the first set of electrical connectors 85 can be coupled to the testing-circuitry connectors 55 and (ii) the second set of electrical connectors 87 are unobstructed for selective coupling with the electrical connectors 324 of a device under test 300. In the particular version shown in FIGS. 1 and 1A, the bracket 120 of each of stabilizers 110A and 110B supports the card-extender 70 by virtue of slidably receiving within the bracket groove 125 thereof the lock member 92 of one of the first and second device locks 90A and 90B, each of which device locks 90A and 90B is secured to one of the first and second edges 78 and 80 of the card-extender 70, as previously described. While device locks 90A and 90B are present in the illustrative version of FIGS. 1 and 1A such that there is “indirect” supporting engagement between each of the first and second edges 78 and 80 of the card-extender 70 and a respective bracket 120, it is to be understood that in alternative versions in which device locks such as 90A and 90B are not used, each of the first and second edges 78 and 80 of a card-extender 70 is supported by slidable receipt into a bracket groove 125 for direct supporting engagement with the bracket 120 of one of the first and second stabilizers 110A and 110B. Based on the preceding explanation, it is to be understood, for purposes of this description, and the appended claims, that “engagement,” “supporting engagement,” and similar terminology employed to describe the relationship between a bracket 120 and one of the first and second edges 78 and 80 of the card-extender 70 contemplates either direct or indirect supporting engagement unless context indicates a contrary interpretation relative to a particular portion of the description or a particular claim.

As previously indicated, each of the stabilizers 110A and 110B includes a mount 140 by which it is secured to the testing-unit housing 25. In the illustrative versions shown in FIGS. 1, 1A and 3, the mounts 140 of, respectively, the first and second stabilizers 110A and 110B comprise first and second elongated posts 145A and 145B extending longitudinally along, respectively, a first post axis A_{P1} and a second post axis A_{P2}. As shown in FIGS. 1 and 1A, the testing-unit housing 25 includes a first structural portion 60 having defined therein a first-post channel 61 and a second structural portion 62 having defined therein a second-post channel 63. In the illustrative version depicted in the drawings, the first and second structural portions are the left and right walls 40 and 42 of the testing-unit housing 25. In various versions, including the version of FIGS. 1 and 1A, the first post 145A and the first-post channel 61 are of mutually complimentary keyed cross-sectional configurations such that the first post 145A, when received within the first-post channel 61, is prevented from rotating about the first post axis A_{P1} (i.e., relative to the first-post channel 61) and the second post 145B and the second-post channel 63 are of mutually complimentary keyed cross-sectional configurations such that the second post 145B, when received within the second-post channel 63, is prevented from rotating about the second post axis A_{P2} (i.e., relative to the second-post channel 63). For the purposes of preventing rotation, it will be appreciated that any cross-sectional geometry other than circular, as viewed into a plane orthogonal to a post axis, is regarded as “keyed.” In still additional, non-illustrated versions in which the mounts 140 are in the form of posts 145, the posts 145 may be otherwise prevented from rotating within the post channels 61 and 63.

With continued reference to FIGS. 1 and 1A, and to FIG. 3, each of stabilizers 110A and 110B includes a stabilizer-bearing surface 130. The stabilizer-bearing surface 130A of the first stabilizer 110A is configured for contacting engagement with a first stabilizer-supporting surface 65 on the testing-unit housing 25. Similarly, the stabilizer-bearing surface 130B of the second stabilizer 110B is configured for contacting engagement with a second stabilizer-supporting surface 66 on the testing-unit housing 25. While the first and second stabilizer-supporting surfaces 65 and 66 are shown as portions of, respectively, the left and right walls 40 and 42 of the testing-unit housing 25, it will be appreciated that the first and second stabilizer-supporting surfaces 65 and 66 may be defined in or on alternative portions of the testing-unit housing 25.

The foregoing is considered to be illustrative of the principles of the invention. Furthermore, since modifications and changes to various aspects and implementations will occur to those skilled in the art without departing from the scope and spirit of the invention, it is to be understood that the foregoing does not limit the invention as expressed in the appended claims to the exact constructions, implementations and versions shown and described.

What is claimed is:

1. A card-extender stabilizing kit for use in conjunction with (a) a computer-device testing unit including testing circuitry having electrical testing-circuitry connectors and being at least partially housed in a testing-unit housing and (b) a card extender having (i) a first connector assembly including a first set of electrical connectors configured for selective coupling with the testing-circuitry connectors, (ii) a second connector assembly, opposite the first connector assembly, and including a second set of electrical connectors configured for selective coupling with the electrical connectors of a device under test, and (iii) opposed and parallel first and second card-extender edges extending between the first and second connector assemblies, the stabilizing kit comprising:
first and second stabilizers, each stabilizer having a mount configured for selective coupling with the housing of a computer-device testing unit and an elongated rigid card-extender bracket including a bracket groove configured for slidably receiving at least one of the first and second card-extender edges;
wherein, when the stabilizers are coupled to a testing-unit housing in an operative mode, the bracket grooves are spaced apart and aligned in parallel such that (i) the card-extender can be positioned between the bracket grooves and supported by virtue of supporting engagement between at least a portion of each of the first and second card-extender edges and one of the card-extender brackets; (ii) the first set of electrical connectors can be coupled to the testing-circuitry connectors and (iii) the second set of electrical connectors are unobstructed for selective coupling with the electrical connectors of a device under test.

2. The kit of claim 1 wherein (i) the mounts of the first and second stabilizers comprise, respectively, a first elongated post extending longitudinally along a first post axis and a second elongated post extending longitudinally along a second post axis and (ii) the testing-unit housing further includes first and second structural portions, the first structural portion having defined therein a first-post channel configured for selective sliding receipt and retention of the first post and the second structural portion having defined therein a second-post channel configured for selective sliding receipt and retention of the first post.

3. The kit of claim 2 wherein (i) the first post and the first-post channel are of mutually complimentary keyed cross-sectional configurations such that the first post, when received within the first-post channel, is prevented from rotating about the first post axis and (ii) the second post and the second-post channel are of mutually complimentary keyed cross-sectional configurations such that the second post, when received within the second-post channel, is prevented from rotating about the second post axis.

4. The kit of claim 3 wherein (i) a device under test configured for coupling with a card extender retained by the first and second stabilizers includes opposed first and second device edges and a third edge that extends between the first and second device edges along which are disposed the electrical connectors of the device under test, and (ii) when a card extender is retained between the card-extender brackets, the bracket grooves extend beyond the second connector assembly of the card extender such that the first and second device edges of a device under test, with the electrical connectors thereof coupled to the electrical connectors of the second connector assembly, are at least partially disposed between the bracket grooves such that the card-extender brackets stabilize the device under test relative to the card extender.

5. The kit of claim 1 wherein (i) a device under test configured for coupling with a card extender retained by the first and second stabilizers includes opposed first and second device edges and a third edge that extends between the first and second device edges along which are disposed the electrical connectors of the device under test, and (ii) when a card extender is retained between the card-extender brackets, the bracket grooves extend beyond the second connector assembly of the card extender such that the first and second device edges of a device under test, with the electrical connectors thereof coupled to the electrical connectors of the second connector assembly, are at least partially disposed between the bracket grooves such that the card-extender brackets stabilize the device under test relative to the card extender.

6. A computer-device testing assembly for testing a card-type computer device including opposed first and second device edges and a third edge that extends between the first and second device edges and along which is disposed a set of electrical connectors configured for electrical coupling to corresponding connectors of testing circuitry, the testing assembly comprising:
a computer-device testing unit including testing circuitry having electrical testing-circuitry connectors and being at least partially housed in a testing-unit housing;
a card extender having (i) a first connector assembly including a first set of electrical connectors coupled with the testing-circuitry connectors, (ii) a second connector assembly, opposite the first connector assembly, and including a second set of electrical connectors configured for selective coupling with the electrical connectors of a computer device for testing the computer device, and (iii) opposed and parallel first and second card-extender edges extending between the first and second connector assemblies;
first and second stabilizers, each stabilizer having a mount coupled with the testing-unit housing and an elongated rigid card-extender bracket including a bracket groove;
wherein (i) the bracket grooves are spaced apart and aligned in parallel; (ii) the card-extender is supported between the bracket grooves of the first and second stabilizers by virtue of supporting engagement between at least a portion of each of the first and second card-extender edges and one of the card-extender brackets and (iii) the second set of electrical connectors is unobstructed for selective coupling with the electrical connectors of a computer device to be tested.

7. The assembly of claim 6 wherein (i) the mounts of the first and second stabilizers comprise, respectively, a first elongated post extending longitudinally along a first post axis and a second elongated post extending longitudinally along a second post axis and (ii) the testing-unit housing further includes first and second structural portions, the first structural portion having defined therein a first-post channel configured for selective sliding receipt and retention of the first post and the second structural portion having defined therein a second-post channel configured for selective sliding receipt and retention of the second post.

8. The assembly of claim 7 wherein (i) the first post and the first-post channel are of mutually complimentary keyed cross-sectional configurations such that the first post, when received within the first-post channel, is prevented from rotating about the first post axis and (ii) the second post and the second-post channel are of mutually complimentary keyed cross-sectional configurations such that the second post, when received within the second-post channel, is prevented from rotating about the second post axis.

9. The assembly of claim 8 wherein the bracket grooves extend beyond the second connector assembly of the card extender such that the first and second device edges of a device under test, with the electrical connectors thereof coupled to the electrical connectors of the second connector assembly, are at least partially disposed between the bracket grooves such that the card-extender brackets stabilize the device under test relative to the card extender.

10. The assembly of claim 6 wherein the bracket grooves extend beyond the second connector assembly of the card extender such that the first and second device edges of a device under test, with the electrical connectors thereof coupled to the electrical connectors of the second connector assembly, are at least partially disposed between the bracket grooves such that the card-extender brackets stabilize the device under test relative to the card extender.

11. The assembly of claim 10 wherein there is physically interposed between each of at least one card-extender bracket and a card-extender edge a third element such that the at least one card-extender bracket, while supporting the card-extender by a card-extender edge, is not in direct physical contact with a card-extender edge.

12. The assembly of claim 11 wherein at least one of the interposed third elements is a device lock for selectively retaining in coupled engagement the electrical connectors of a device to be tested with the second set of electrical connectors on the card extender.

13. The assembly of claim 6 wherein there is physically interposed between each of at least one card-extender bracket and a card-extender edge a third element such that the at least one card-extender bracket, while supporting the card-extender by a card-extender edge, is not in direct physical contact with a card-extender edge.

14. The assembly of claim 13 wherein at least one of the interposed third elements is a device lock for selectively retaining in coupled engagement the electrical connectors of a device to be tested with the second set of electrical connectors on the card extender.
